(19) United States
(12) Patent Application Publication
(10) Pub. No.: US 2026/0085447 A1
(43) Pub. Date: Mar. 26, 2026

(54) FABRICATION OF LARGE AND POLYMER-FREE COMPLEX OXIDE AND COMPLEX NITRIDE MEMBRANES ASSISTED BY ISOLATED METAL ISLANDS

(71) Applicant: Wisconsin Alumni Research Foundation, Madison, WI (US)

(72) Inventors: Chang-Beom Eom, Madison, WI (US); Pratap Pal, Madison, WI (US); Yuchuan Yao, Madison, WI (US)

(21) Appl. No.: 18/897,238

(22) Filed: Sep. 26, 2024

(51) Int. Cl. C30B 25/20; B01D 67/00; B01D 71/02; C30B 29/24

(52) U.S. Cl. CPC C30B 25/20; B01D 67/0072; B01D 71/0271; C30B 29/24; B01D 2323/21813; B01D 2323/35; B01D 2325/04; B01D 2325/46

(57) ABSTRACT

High-quality membranes of complex oxide and complex nitrides are provided. Also provided are method of making the membranes by releasing films of the complex oxides and nitrides from an epitaxial heterostructure using metal islands on the surface of the films as strain-absorbing supports. The methods facilitate the release of flat, large-area membranes characterized by the absence of, or a very low density of, cracks and/or wrinkles. The released membranes are free of the surface organic residues that are present on membranes released with the aid of a polymer support.

### REFERENCE TO GOVERNMENT RIGHTS

This invention was made with government support under DE-FG02-06ER46327 awarded by the US Department of Energy and under N00014-20-1-2844 awarded by the NAVY/ONR. The government has certain rights in the invention.

### BACKGROUND

Complex-oxide thin-films offer exotic physical properties like ferroelectricity, magnetism, piezoelectricity, metal-to-insulator transitions, superconductivity, other interface-related emergent phenomena, such as two-dimensional (2D) electron gas formation, and magnetic exchange bias, which are not found in common semiconductors such as Si, Ge, GaAs, or GaN. Thus, these materials can be used in many device applications where the usefulness of conventional semiconductors is limited. However, for epitaxial thin-film heterostructures, the active material is clamped to an underlying substrate, which limits the full potential functionality of the material. Also, intrinsic properties of thin-films having thicknesses of only a few nanometers may be restricted by the substrate. In contrast, free-standing membranes of complex oxides, fabricated by releasing the membrane from the underlying substrate, are advantageous because they can maintain their intrinsic material properties and can be integrated into device structures with a wide range of other materials, which is not possible for thin films in conventional epitaxial heterostructures. The release of strain in the membranes upon release can lead to the recovery of bulk-like physical properties. For example, strained BiFeO₃ (BFO) clamped to a substrate lose their spin-cycloid at thicknesses of less than about 200 nm. (Kc, X. et al. Phys. Rev. B—Condens. Matter Mater. Phys. 82, 1-5 (2010); Burns, S. R. et al. npj Quantum Mater. 4, 1-8 (2019).) However, a free-standing membrane of BFO can exhibit bulk-like properties and recover its spin cycloid even at thicknesses lower than 200 nm.

Efforts have been made towards the realization of free-standing membranes of complex oxides, including the first demonstration of etching a sacrificial, water-soluble Sr₂CaAl₂O₆ (SCAO) layer to release an overlying free-standing SrTiO₃ membrane. (Lu, D. et al. Nat. Mater. 15, 1255-1260 (2016).) Since then, a lot of progress has been made toward the investigation of such complex oxide membranes, and other methods have been developed for membrane fabrication, transfer, and integration. (Cai, S. et al. Nat. Commun. 13, 1-10 (2022); Chen, Z. et al. Phys. Rev. Mater. 3, 1-6 (2019); and Li, Y. et al. Adv. Mater. 34, 1-12 (2022).)

The two main steps toward the fabrication of free-standing complex oxide membranes are the release of a complex oxide layer from a substrate upon which it is grown and the subsequent transfer of the released membrane to a desired platform or another substrate. Regarding the release of the membrane from the substrate, the common methods are: (a) chemical lift off, where an underlying sacrificial layer is etched either by water or other solutions, (b) remote epitaxy, where a thin film (e.g., 2-monolayers) of graphene is disposed on top of a substrate and a complex oxide material is grown on the substrate, through the graphene, following by the peeling-off of the membrane; and (c) mechanical exfoliation, using a stressor layer (e.g., thick Ni on top of the active material). (Shi, Q. et al. Nat. Commun. 13, 1-10 (2022); Lu, D. et al. Nat. Mater. 15, 1255-1260 (2016); Jang, H. W. et al. Appl. Phys. Lett. 92, 8-11 (2008); Kim, S. I. et al. Mater. Horizons 7, 1552-1557 (2020); Kum, H. S. et al. Nature 578, 75-81 (2020); and Yoon, H. et al. Sci. Adv. 8, 1-7 (2022).)

The transfer of a released membrane can be done directly, without any top support (“stamp”), by just scooping the membrane out of a solution in which it has been released, or indirectly with a top polymer support. (Eom, K. et al. Sci. Adv. 7, 1-8 (2021); Jani, H. et al. Nat. Mater. 23, 619-626 (2024).) Without using a polymer support, it is very difficult to stabilize a large-size membrane, which leads to cracking of the membrane and limits the membrane size. Various top supporting layers have been identified for the direct transfer approach, such as polymethyl methacrylate (PMMA), polypropylene carbonate (PPC), and polydimethylsiloxane (PDMS). (Seung Sae Hong et al., Science (80-.) 368, 71-76 (2020); Lindemann, S. et al. Sci. Adv. 7, 1-9 (2021).) However, the polymer supports must be removed after the successful transfer of the membrane, and this leads to the cracking of the membrane and residual polymer on the membrane surface, which is not ideal for follow up device fabrication. Another challenge for complex oxide membranes is that they are very brittle, so cracks form when strain is released in the membrane upon its release from the substrate. Moreover, even after membrane transfer, bubbles, wrinkles, and/or polymer residues are present in or on the membrane.

### SUMMARY

Methods of making free-standing, high-quality membranes of complex oxides and complex nitrides are provided.

One embodiment of a method of forming a membrane includes the steps of: (a) providing an epitaxial heterostructure comprising: a substrate; a strained film comprising a single-crystal complex oxide or a single-crystal complex nitride; and a sacrificial layer between the substrate and the strained film; (b) forming metal islands on the top surface of the strained film; and (c) immersing the epitaxial heterostructure in a liquid comprising an etchant to selectively etch away the sacrificial layer and release the strained film from the epitaxial heterostructure as a membrane of the single-crystal complex oxide or the single-crystal complex nitride, wherein the membrane is released without a top support, other than the metal islands, on its top surface. The released membranes can be transferred onto a support platform for subsequent integration into a variety of electronic devices.

One example of a supported complex nitride membrane that can be formed using the present methods includes a membrane bilayer comprising a sublayer of an antiperovskite manganese nitride, such Mn₃GaN, Mn₃SnN, Mn₃NiN, or Mn₃PtN, and an adjacent sublayer of SrTiO₃ disposed on a surface of a support platform. Because the bilayer is not grown epitaxially on the support platform, the SrTiO₃ sublayer is in contact with, but does not form an epitaxial interface with, the surface of the support platform.

Another example of a supported complex oxide membrane that can be formed using the present methods consists of one or more layers of single-crystal perovskite oxide on a surface of a support platform, wherein the one or more layers of single-crystal perovskite oxide are free polymer residues and free of cracks and wrinkles over an area of at least 10 mm². Again, because the perovskite oxides are not grown epitaxially on the support platform, they are in contact with, but do not form an epitaxial interface with, the surface of the support platform.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 shows a schematic illustration of a process for releasing a strained complex oxide or complex nitride thin-film for a heterostructure.

FIGS. 2A-2C show schematic diagrams for the (001) single domain BiFeO₃ membrane makings of FIG. 2A without any top support, FIG. 2B with top PMMA followed by PPC polymer coating, and FIG. 2C with isolated top metallic Pt electrodes that are circular in shape, in accordance with Example 1. FIGS. 2D-2F display corresponding optical images of the etched membrane floating in water. While without support, the membrane breaks into small pieces, it can maintain large size with support either from PMMA/PPC or top isolated Pt electrodes. FIGS. 2G-21 display the collected membrane on Si without support and on Al₂O₃ for membranes with support. Without any top support, the membrane does not stabilize in large size. In the case of top polymer support, it leads to some cracks and even after cleaning with acetone, a lot of polymer residue remains. However, in the case of top isolated Pt electrodes, a large (˜2.5×2.5 mm²) membrane is stabilized, which is as good as the thin-film.

FIGS. 3A-3D. Basic 2D COMSOL simulations are shown to understand the membrane etching phenomena (FIG. 3A) without top Pt electrodes and (FIG. 3B) with top Pt electrodes. Here, parameters used for BiFeO₃ are mass density=8.31×10³ kg/m³, Young's modulus: 214 Gpa, and Poisson's ratio: 0.49. Similar parameters for Pt electrodes are mass density: 2.14×10⁴ kg/m³, Young's modulus: 168 GPa, and Poisson's ratio: 0.38 at room temperature. The size of Pt electrode used is of 200 μm diameter. FIGS. 3C-3D show calculated strain profile for both configurations. Here, Pt electrodes help in localizing strain around it and reduce overall strain as compared to that without top Pt electrodes, which in turn stabilizes the large-size BiFeO₃ membrane.

FIGS. 4A-4B show room temperature X-ray diffraction spectra for (FIG. 4A) 300 nm (001) BiFeO₃ thin-film on SrTiO₃ and (FIG. 4B) 300 nm BiFeO₃ membrane collected on Al₂O₃. FIGS. 4C-4D display their corresponding atomic force microscopy (AFM) images exhibiting similar surface quality without any degradation during the etching process. FIGS. 4E-4F show respective reciprocal space mapping images indicating single ferroelastic domain nature for both the film and the membrane.

FIG. 5A shows an out-of-plane piezo-force-microscopy (PFM) image of a BiFeO₃ membrane, which shows single contrast in the as-grown region, which is reversed by a negative applied electric field as shown under the highlighted box. FIG. 5B shows an optical microscopy image of a representative BiFeO₃ membrane used for ferroelectric measurements. FIG. 5C shows ferroelectric polarization vs electric field (PE) loops for BiFeO₃ thin-film and the corresponding membrane taken at 10 KHz frequency. FIG. 5D shows a schematic drawing of the potential energy well for up and down polarization states in the case of BiFeO₃ film and membrane. As there is an imprint in the BiFeO₃ thin-film with a preferred down-polarization after release although coercive field is reduced, it maintains its preferred down-polarization state without losing its single ferroelectric domain nature. FIG. 5E shows fatigue measurement data on 300 nm BiFeO₃ film and membrane for an applied square electric field pulse of 300 kV/cm. The inset to FIG. 5A shows the FE polarization switching pulse that was applied. FIG. 5F shows the variation of total switched ferroelectric polarization with the applied pulse width for different applied voltages. The BiFeO₃ membrane switches at lower voltage with faster time dynamics.

FIG. 6A shows a large area optical image of a BiFeO₃ membrane fabricated without any top support method. FIG. 6B shows a corresponding AFM image. Here, although the membranes are formed with small pieces because of having no top support, their surfaces remain as good as thin-film.

FIG. 7A shows a large area optical image of a BiFeO₃ membrane fabricated with top PMMA/PPC polymer support. FIG. 7B shows a corresponding AFM image. Here, although the membranes are formed with large sizes because of having rigid top support, their surfaces have poor quality, relative to the surface of a thin-film, and there is always some polymer residue even after cleaning with acetone, which may limit follow up device fabrication.

FIGS. 8A-8B show optical microscopy images of a 100 nm BiFeO₃ membrane (FIG. 8A) with ˜25 nm Au electrodes and (FIG. 8B) after removal of Au electrodes using KI solution. FIGS. 8C-8D show AFM images (FIG. 8C) before Au removal and (FIG. 8D) after Au removal. These images clearly show that the Au etching solution can completely dissolve Au and results in a membrane with similar quality as good as the thin-film.

FIG. 9 shows cross sections of the corresponding (−103) peaks of the RSM scans shown in FIGS. 3A-3D. Interestingly, the FWHM of these sections come out to be similar to both thin-film and the membrane indicating no degradation of structural quality due to the etching process.

FIG. 10A shows a schematic illustration of the electric field pulse used for PE loop measurements. Here, no negative pulse preset was used. FIG. 10B shows variation of polarization with electric field at 10 kHz frequency. At the start, saturation positive polarization was observed, which indicates that all FE dipoles are aligned in the same downward direction for both thin-film and the membrane, as expected for a single FE domain BiFeO₃.

FIG. 11 shows a schematic illustration of the polarization rotation in a BiFeO₃ membrane due to the release of compressive strain of BiFeO₃ thin-films on SrTiO₃ substrates. Due to release of strain c/a reduces in case of membrane, resulting in a polarization rotation which is responsible for the reduced polarization as compared to its thin-film form.

FIG. 12 shows that frequency dependent variation of ferroelectric switching field is relatively less dispersive for both the thin-film and the membrane.

FIG. 13A, 13B, and 13C illustrate the effect of metal island shape, size, and density on the strain distribution in the BFO membranes was also studied using 2D Comsol simulations. FIG. 13A shows strain distribution images and line-cuts for a circular and a square Pt island on a BFO membrane. FIG. 13B shows strain distribution images and line-cuts for differently sized circular Pt islands on a BFO membrane. FIG. 13C shows strain distribution images for BFO membranes with different circular Pt island densities.

FIG. 14A is a schematic illustration of a method of forming a free-standing complex nitride membrane comprising the antiperovskite nitride, Mn₃GaN.

FIG. 14B shows an optical microscopy image of a large Mn₃GaN membrane supported by isolated top metal electrodes in accordance with Example 2.

FIGS. 14C and 14D show out-of-plane X-ray diffraction data for a SrTiO₃ (002) peak for an SrTiO₃/Mn₃GaN bilayer thin film (FIG. 14C) and membrane (FIG. 14D), as described in Example 2. FIGS. 14E and 14F show atomic force microscopy images of the SrTiO₃/Mn₃GaN thin film and membrane, respectively, of Example 2.

FIGS. 15A and 15B show sheet resistance versus temperature plots for the SrTiO₃/Mn₃GaN bilayer thin film (FIG. 15A) and membrane (FIG. 15B), in accordance with Example 2.

FIGS. 15C and 15D show temperature-dependent magnetization plots for the SrTiO₃/Mn₃GaN bilayer thin film (FIG. 15C) and membrane (FIG. 15D), in accordance with Example 2.

### DETAILED DESCRIPTION

High-quality membranes of complex oxides and complex nitrides are provided. Also provided are method of making the membranes by releasing strained films of the complex oxides and nitrides from an epitaxial heterostructure using metal islands on the surface of the films as strain-absorbing supports. The methods facilitate the release of flat, large-size membranes characterized by the absence of, or a very low density of, cracks and/or wrinkles. The released membranes lack the surface organic residues that are present on membranes released with the aid of a polymer support.

The metal islands on the surface of the complex oxide or nitride film serve to distribute strain homogeneously in the film while it is released, thereby eliminating, or reducing the density of, cracks formed during the release of the film and preventing the film from breaking into small pieces when the film is released as a free-standing membrane. As a result, the methods described herein can form flat, continuous, large-area complex oxide or complex nitride membranes having a lower density of cracks and fewer wrinkles than membranes of the same composition and size that are released without a top support or with a single continuous metal film as a top support.

As used herein, the terms complex oxide and complex nitride refer to inorganic metal oxides or inorganic metal nitrides comprising two or more metal elements. The methods are particularly useful for the fabrication of perovskite oxides and nitrides and anti-perovskite oxide and nitride membranes which, due to their brittle nature, have proven challenging to fabricate as smooth, large-area, crack-free membranes. Perovskite oxides and nitrides have a crystal structure with the formula ABO₃ or the formula ABN₃, where A is a larger cation, such as Bi³⁺, Sr²⁺, Ba²⁺, Rb⁺, or a lanthanide 3+ cation and B is a smaller transition metal ion. In the structure, each B cation is coordinated by six anions, forming a BX₆ octahedron centered on the cation, where X is oxygen or nitrogen.

The anti-perovskite oxides and nitrides have a structure in which the cations and anions occupy the opposite positions relative to the perovskites. Anti-perovskites have a crystal structure with the formula X₃AB formula, where X represents a metal cation, such as a transition metal, alkaline metal, and alkaline-earth metal cation, A is a larger anion, such as p-group element, and B is an oxygen or nitrogen anion.

The methods begin with an epitaxial heterostructure grown on a substrate. Epitaxial growth of the heterostructure can be carried out using a variety of physical and chemical vapor deposition methods, including pulsed laser deposition (PLD) and molecular beam epitaxy (MBE). The different layers in an epitaxial heterostructure are characterized by interfaces in which the crystallographic orientation of an overlying layer is controlled by that of the previously-deposited underlying layer, such that the materials in the different layers are forced to have the same crystalline arrangement right at the interface. As a result, the complex oxide or nitride film is clamped by the substrate and any inherent lattice mismatch between the two materials results in strains and stresses in the heterostructure layers. The clamping of the films can change the properties of the films and can even eliminate certain useful properties found in the corresponding bulk materials.

In the starting heterostructures, the substrate is selected based on the sacrificial material and the complex oxide or nitride films to be grown thereon; the lattice mismatch between the different materials in the heterostructure should be sufficiently small that a high-crystal quality sacrificial layer can be grown epitaxially on the substrate and a single-crystal film of a complex oxide or complex nitride can be grown epitaxially over the sacrificial layer. For this reason, complex oxides and nitrides are also typically good candidates for the substrate and sacrificial layers in the heterostructures. The sacrificial layers are composed of a sacrificial material that is characterized by the ability to be selectively wet-etched using an etchant that does not significantly etch the overlying complex oxide or complex nitride film. The sacrificial material desirably dissolves in water. However, sacrificial materials that dissolve in non-aqueous organic solvents can also be used. In one embodiment of the methods, the complex oxide film is a BiFeO₃/SrRuO₃ (BFO/SRO) bilayer on a Sr₂CaAl₂O₆ sacrificial layer on a SrTiO₃ (001) substrate. Other illustrative embodiments are described below.

Water soluble complex oxides that can be used as sacrificial materials for a variety of complex perovskite oxides include the (Ca,Sr,Ba)₃Al₂O₆ family of oxides. This family of oxides include at least one of the metals Ca, Sr, and Ba, but may include a combination of two or three of these metals. Thus, this family of oxides includes Sr₃Al₂O₆ (SAO), Sr₂CaAl₂O₆ (SCAO), Sr_{1.5}Ca_{1.5}Al₂O₆, and Ba₃Al₂O₆ (BAO). Other suitable oxides that can be used as sacrificial layers include perovskite oxides, such as LaₓSr₁₋ₓMnO₃, where 0<x<1, (LSMO; e.g., La_{0.7}Sr_{0.3}MnO₃ and La_{0.67}Sr_{0.33}MnO₃), SrRuO₃ (SRO), and SrVO₃ (SVO). Illustrative examples of substrate materials for these perovskite oxides and other complex oxides are SrTiO₃ (STO) and GdScO₃ (GSO).

Perovskite oxides that can be grown epitaxially on the above-mentioned sacrificial materials include SrTiO₃, LaₓSr₁₋ₓMnO₃, BaTiO₃, BiFeO₃, SrRuO₃, LaNiO₃, BiMnO₃, Sr₂IrO₄, La_{0.7}Ca_{0.3}MnO₃, [(La_{0.7}Ca_{0.3}MnO₃)₅/(SrTiO₃)₅]ₙ, BaTiO₃/La_{0.7}Sr_{0.3}MnO₃, BaTiO₃/La_{0.7}Sr_{0.3}MnO₃/BaTiO₃, LaAlO₃/YBa₂Cu₃O₇₋ₓ/LaAlO₃, La_{0.7}Sr₃MnO₃/BiFeO₃, BaTiO₃—CoFe₂O₄, PbTiO₃, n-SrTiO₃/n-PbTiO₃/n-SrTiO₃, [(PbTiO₃)₁₆/(SrTiO₃)₁₆]₈, Ba₃Al₂O₆, PbZr_{0.2} Ti_{0.8}O₃, [(CaTiO₃)ₙ/(SrTiO₃)ₙ]₆, BiFeO₃/SrRuO₃, LiFe₅O₈, SrRuO₃/BaTiO₃/SrRuO₃, Ba₁₋ₓSrₓRuO₃/Ba₁₋ₓSrₓTiO₃/Ba₁₋ₓSrₓRuO₃, La_{0.7}Sr_{0.3}MnO₃, La_{0.7}Sr_{0.3}MnO₃, BaTiO₃/SrTiO₃, and CaFe₂O₄.

Descriptions of methods of growing epitaxial heterostructures with compatible substrates, sacrificial layers, and complex oxide films, and suitable selective etchants for the sacrificial layers, with citations to the scientific literature, can be found in Chiabrera, Francesco M., et al. “Freestanding perovskite oxide films: Synthesis, challenges, and properties.” Annalen der Physik 534.9 (2022): 2200084. Listings of examples of materials for the epitaxial heterostructures that can be used to form free-standing complex oxide membranes are provided in Table 1.

TABLE 1
Examples of Epitaxial Heterostructure Materials

| Complex Oxide | Sacrificial Material | Substrate |
|---|---|---|
| SrTiO₃ | Sr₃Al₂O₆ | SrTiO₃ (001) |
| LaₓSr₁₋ₓMnO₃ | Sr₃Al₂O₆ | SrTiO₃ (001) |
| BaTiO₃ | Sr₃Al₂O₆ | SrTiO₃ (110) |
| BiFeO₃ | Sr₃Al₂O₆ | SrTiO₃ (110) |
| SrRuO₃ | Sr₃Al₂O₆ | SrTiO₃ (111) |
| LaNiO₃ | Sr₃Al₂O₆ | SrTiO₃ (111) |
| BiMnO₃ | Sr₃Al₂O₆ | SrTiO₃ (111) |
| Sr₂IrO₄ | Sr₃Al₂O₆ | SrTiO₃ (111) |
| La_{0.7}Ca_{0.3}MnO₃ | Sr₃Al₂O₆ | SrTiO₃ (111) |
| [(La_{0.7}Ca_{0.3}MnO₃)₅/(SrTiO₃)₅]ₙ | Sr₃Al₂O₆ | SrTiO₃ (111) |
| BaTiO₃/La_{0.7}Sr_{0.3}MnO₃ | Sr₃Al₂O₆ | SrTiO₃ (111) |
| BaTiO₃/La_{0.7}Sr_{0.3}MnO₃/BaTiO₃ | Sr₃Al₂O₆ | SrTiO₃ (111) |
| LaAlO₃/YBa₂Cu₃O₇₋ₓ/LaAlO₃ | Sr₃Al₂O₆ | SrTiO₃ (111) |
| La_{0.7}Sr3MnO3/BiFeO3 | Sr₃Al₂O₆ | SrTiO₃ (111) |
| BiFeO₃/La_{6.7}Sr_{0.33}MnO₃ | Sr₃Al₂O₆ | SrTiO₃ (111) |
| BaTiO₃_{^{−}}CoFe₂O₄ | Sr₃Al₂O₆ | SrTiO₃ (111) |
| SrTiO₃ | Sr₃Al₂O₆ | SrTiO₃ (001) |
| BiFeO₃ | Sr₃Al₂O₆ | SrTiO₃ (001) |
| PbTiO₃ | Sr₃Al₂O₆ | SrTiO₃ (001) |
| SrTiO₃ | Sr₂CaAl₂O₆ | SrTiO₃ (001) |
| n-SrTiO₃/n-PbTiO₃/n-SrTiO₃ | Sr₂CaAl₂O₆ | SrTiO₃ (001) |
| [(PbTiO₃)₁₆/(SrTiO₃)₁₆]₈ | Sr₂CaAl₂O₆ | SrTiO₃ (001) |
| SrRuO₃ | Sr_{1.5}Ca_{1.5}Al₂O₆ | SrTiO₃ (001) |
| La_{0.7}Ca_{0.3}MnO₃ | SrCa₂Al₂O₆ | SrTiO₃ (001) |
| La:BaSnO₃ | Ba₃Al₂O₆ | SrTiO₃ (001) |
| PbZr_{0.2}Ti_{0.8}O₃ | La_{0.7}Sr_{0.3}MnO₃ | SrTiO₃ (001) |
| [(CaTiO₃)ₙ/(SrTiO₃)ₙ]₆ | La_{0.67}Sr_{0.33}MnO₃ | SrTiO₃ (001) |
| BiFeO₃/SrRuO₃ | La_{0.67}Sr_{0.33}MnO₃ | GdScO₃(110) |
| LiFe₅O₈ | La_{0.67}Sr_{0.33}MnO₃ | GdScO₃(110) |
| SrRuO₃/BaTiO₃/SrRuO₃ | La_{0.67}Sr_{0.33}MnO₃ | GdScO₃(110) |
| Ba₁₋ₓSrₓRuO₃/Ba₁₋ₓSrₓTiO₃/ | La_{0.67}Sr_{0.33}MnO₃ | GdScO₃(110) |
| Ba₁₋ₓSrₓRuO₃ | | |
| BaTiO₃ | La_{0.67}Sr_{0.33}MnO₃ | GdScO₃(110) |
| La_{0.7}Sr_{0.3}MnO₃ | SrRuO₃ | SrTiO₃(001) |
| SrTiO₃ | SrVO₃ | SrTiO₃(001) |
| YBa₂Cu₃O₇ | SrRuO₃ | SrTiO₃(001) |
| YBa₂Cu₃O₇ | La_{0.7}Sr_{0.3}MnO₃ | SrTiO₃(001) |

Examples of antiperovskite complex metal nitride films that can be released from a heterostructure using the methods described herein include complex manganese nitrides, such as Mn₃GaN, Mn₃SnN, Mn₃NiN, and Mn₃PtN. The complex manganese nitride films can be grown on an STO film that is itself grown on a scarificial SCAO layer on a substrate, such as a (001)- or (111)-oriented SrTiO₃ substrate. The complex manganese nitride film and the STO film can then be released as a free-standing bilayer membrane by the selective etching of the SCAO layer. The release of the complex manganese nitride films can be carried out with or without the aid of the metal islands. However, as described herein the use of the metal islands facilitates the release of a large-size, high-quality, organic residue-free membrane.

As illustrated in some of the examples provided in Table 1, the complex oxide or complex nitride film need not be composed on a single material. In some embodiments of the epitaxial heterostructures, the complex oxide or complex nitride film to be released as a free-standing membrane is composed of two or more sub-layers of complex oxide or complex nitride, each of which may be grown as a single-crystal. (In Table 1, the sublayers in a complex oxide film with multiple sublayers are separated by a backslash, “/”.) In some embodiments, the strained film and the released membrane are bilayers. In some such bilayers, the bottom sublayer may be chosen so that it acts as an electrode in an electronic device into which the membrane is incorporated. The complex oxides or nitrides of the films and membranes may be doped to tailor their properties for an intended application.

The thickness of the complex oxide or complex nitride film will depend on the intended application for the released membrane. However, for both the sacrificial layer and the complex oxide or nitride films, thicknesses below the critical thickness are generally preferred. Additionally, because the membranes are generally designed for incorporation into thin film-based electronic devices, the complex oxide and complex nitride films will typically have a thickness of 500 nm or lower, including embodiments in which the thickness of the complex oxide or complex nitride film is 400 nm or lower, 300 nm or lower, 200 nm or lower, 100 nm or lower, or 50 nm or lower. By way of illustration, complex oxide or complex nitride films and their corresponding released membranes may have thicknesses in the range from the thickness of one unit cell to a thickness of 500 nm, including thicknesses in the range from 50 nm to 200 nm. For membranes composed on multiple sublayers of complex oxide or nitride, such as bilayer membranes, these thicknesses refer to the total membrane thickness. The optimal thickness of the sacrificial layer may also depend on how quickly the sacrificial material is able to dissolve. Generally, sacrificial layer thicknesses in the range from about 5 nm to about 20 nm are practical. However, layer thicknesses outside the ranges described here can be used.

The methods described herein can produce large-area free-standing membranes from large-area strained films, wherein the area corresponds to the surface area of the top surface of the complex oxide or complex nitride film. By way of illustration, the complex oxide or complex nitride film (and, therefore, its released complex oxide or complex nitride membrane) may have a top surface area of 1 cm² or greater, 2 cm² or greater, 5 cm² or greater, or even 10 cm² or greater, as measured by the lateral dimensions of the top surface of the film or membrane. (As used herein, the lateral dimensions are the length and width dimensions of a membrane—i.e., the dimensions orthogonal to the thickness dimension.)

Once the epitaxial heterostructure is grown, metal islands are deposited on the exposed surface of the complex oxide or complex nitride film. Because metals are more ductile than the complex oxides and nitrides, the islands localize high strains beneath of the islands, while homogenizing and reducing the overall strain throughout the film during the release of the membrane, thereby preventing or minimizing the formation of cracks. The metal islands desirably, but not necessarily, form a regular pattern on the surface of the film. For example, the metal islands may form a square array or hexagonal array with a uniform pitch between the islands. Arrays of metal islands on the large-area films and membrane may include, for example, at least 10, at least 100, or at least 1000 metal islands. The metal islands can have a variety of shapes including, but not limited to, circular, square, rectangular, and triangular. The size, shape, and density of the metal islands can be selected to localize high strains and reduce overall strain relative to the strain in a membrane that is released without a support. The optimal size, shape and density of the metal islands will depend on the complex oxides or nitrides and metal being used, as well as the layer/film thicknesses and degree of strain in the clamped film. However, as illustrated by the guidance provided in Example 1, 2D COMSOL simulations can be used to simulate the strain distribution profile in a film for a given metal island configuration and to ascertain appropriate metal island shapes, sizes, and densities. By way of illustration, metal islands having a maximum lateral dimension (e.g., diameters) in the range from 50 μm to 1000 μm, including in the range from 200 μm to 600 μm and in the range from 200 μm to 400 μm, and/or thicknesses in the range from 20 nm to 100 nm, including in the range from 20 nm to 50 nm, are generally suitable. However, dimensions outside of these ranges can be used, provided that the islands are sufficiently thick to absorb and localize strain during the release of the membrane. The metal islands can be formed on the film surface using known deposition techniques, such as sputtering and evaporation.

Regarding island shape, circular shaped islands have been found to be particularly well suited to homogenizing and minimizing the strain during release of the membranes. This is illustrated in Example 1, which shows that, relative to square islands, circular islands are better able to reduce overall strain in a film as it is released from a substrate.

Regarding island densities, it has been found that films and their corresponding free-standing membranes in which 20% to 30% of the surface area of the film or membrane is covered by metal islands are particularly well suited for distributing strain across the membrane and reducing the overall strain.

The metal of the islands may be a single (elemental) metal or a metal alloy that includes two, three, or more metal elements. If the metal islands will be incorporated into a final device (e.g., as electrodes) along with the complex oxide or complex nitride membrane, the metal should be one that bonds strongly to the complex oxide or nitride. However, the metal islands can also be removed from the released membrane prior to incorporating the membrane into a device. Advantageously and unlike polymer supports, the metal island supports can be removed from the membranes without degrading the surface or crystal quality of the membrane and without leaving any material residue using a chemical etch. Platinum (Pt) is an example of a metal that bonds strongly to complex oxides, such as BFO, and complex nitrides, while gold (Au) is more readily removed. Silver (Ag) is another example of a suitable island material. In some embodiments, the metal of the metal islands is not copper and, in some embodiments, it is not gold. If maintaining the stoichiometry of the complex metal oxide or complex metal nitride is important, the metal used in the islands should be one that does not react with the complex oxides or complex nitrides to form the corresponding metal oxides and metal nitrides, as such reactions will remove oxygen from the complex oxide or nitrogen from the nitride membrane.

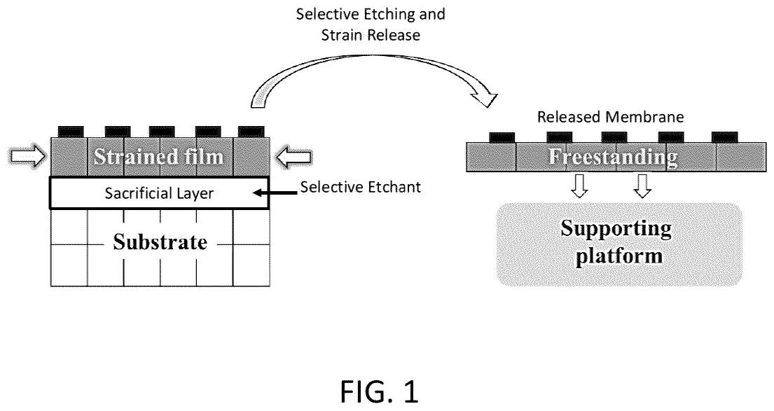

Once the heterostructure has been fabricated and the metal islands patterned on the strained film, the sacrificial layer is selectively etched away to release the complex oxide or complex nitride film from the substrate, thereby converting the film into a free-standing membrane, which can be transferred to another supporting platform for subsequent processing and/or device fabrication. This is shown schematically in the diagram of FIG. 1. The supporting platform may be temporary support or may be support that will ultimately be incorporated into a final electronic device as a device substrate. Examples of supporting platforms are inorganic semiconductor substrates, (e.g., Group III-V, Group II-VI, or Group IV substrates, such as a silicon substrate), dielectric substrates, such as a silicon oxide substrate, or polymer substrates, such as a PMMA substrate. The surface of a supporting platform on which a released membrane is disposed will typically have an area that is the same size as, or larger than, the lateral area of the membrane such that the membrane and the supporting platform are in contact over most or all of the contacting surface of the membrane.

The selective etching of the sacrificial layer is carried out by exposing the sacrificial material to liquid or vapor etchant that selectively etches the sacrificial material without significantly etching the complex oxide or complex nitride film. One way of doing this is by immersing the epitaxial heterostructure in a liquid etchant or a liquid solution containing the etchant, whereby the membrane is released into the liquid, and then lifting (“scooping”) the released membrane out of the liquid with a supporting platform. After removal from the liquid using a supporting platform with a planar surface, the membrane lies flat on the planar surface of a supporting platform, without rolling into a tube or coil. A released membrane is “free-standing” in that it does not require a supporting substrate to provide it with structural integrity and is not fixed to a substrate at an epitaxial interface. The released complex oxide or complex nitride membranes can be released in a strain-free state or, in the case of a membrane comprising two or more sub-layers, may be released in an elastic strain-sharing state. In either case, the released membrane is in a lower strain state than its corresponding strained and clamped film.

Flat, large-area, high-crystal-quality membranes that are free of any organic (e.g., polymer) residue can be released. This includes released membranes having a continuous area with a minimum lateral dimension (e.g., length and/or width) of at least 2 mm, at least 2.5 mm, and at least 5 mm (e.g., in the range from 2 mm to 20 mm). By way of illustration, wrinkle free areas within a membrane may have dimensions of at least 2 mm×2 mm, at least 2.5 mm×2.5 mm, and 5 mm×5 mm, or larger that are free of cracks and wrinkles. The flatness (wrinkle-free nature) of a membrane refers to flatness once the membrane has been transferred to a supporting platform (i.e., after removal from the liquid etchant or etchant solution), as the membrane may not adopt a planar geometry while in, or floating on, the etchant liquid or solution. The crack-free area of a membrane refers to the area of the membrane while it remains in the etchant liquid or solution or after is has been transferred to a supporting platform. Care should be taken while removing the membrane from the etchant liquid or solution to avoid new crack formation during the removal and transfer.

The high-quality, crystalline membranes can be incorporated in a variety of electronic devices, such as magnetic memory and logic devices, field-effect transistors, spintronic devices, electro-optic modulators, photovoltaic devices, and radiation detectors. To incorporate a membranes into an electronic device, the membrane can be bonded to a variety of device substrates, including device substrates upon which the complex oxide or complex nitride could not be grown epitaxially and/or flexible substrates, such as polymeric substrates. The device substrate may be, but need not be, a supporting platform that was used to scoop the free-standing membrane out of the etching liquid. The device substrate may itself be a heterostructure comprising two or more layers of material. Once the membrane has been transferred to a device substrate, it is possible to deposit additional device layers or components on the membrane. This may be accomplished using epitaxial growth or other deposition techniques. The device substrate onto which the released membrane is transferred is not particularly limited, since the release-and-transfer approach allows for stacking layers at non-epitaxial interfaces. At these non-epitaxial interfaces, the material in one layer can have a crystallographic orientation that is independent from (e.g., different from) that of an adjacent layer and the interface is free from lattice mismatch-induced strains and stresses.

The methods described herein are particularly useful for the fabrication of thin, large-area, single-crystalline BFO membranes because they can produce unstrained, crack-free, wrinkle-free, organic residue-free BFO membranes having a single ferroelastic, single ferroelectric, and single antiferromagnetic domain (i.e., monodomain BFO membranes). The released BFO membranes provide a lower ferroelectric switching field at frequencies in the range from 1×101 to 1×105 Hz and a faster switching response than the corresponding heterostructure-clamped BFO films. Ferroelectric switching fields and responses in the BFO membranes can be at least 20% (e.g., from 20% to 50% lower) and at least 60% (e.g., from 60% to 90% lower), respectively, than the ferroelectric switching fields and responses for their BFO film counterparts. Moreover, because the BFO membranes are not strained, they are able to retain their spin-cycloid, even at membrane thicknesses of 200 nm or lower. Methods for fabricating monodomain BFO membranes are described in detail in Example 1 and the procedures in the Example can be used to produce other complex oxide and complex nitride membranes, including other monodomain, unstrained, crack-free, wrinkle-free, organic residue-free ferroelectric membranes, such as PbTiO₃ (PTO) and BiTiO₃ (BTO) membranes. The ferroelectric membranes can be incorporated into magnetoelectric memory devices and logic devices and other electronic devices where switchable ferroelectric polarization of other properties of the membranes are beneficial.

### EXAMPLES

### Example 1: Fabrication of Free-Standing Complex Oxide Membranes

This Example illustrates the fabrication of a large-size, free-standing BFO membrane with few cracks, or wrinkles, and without any degradation of its quality. The BFO membrane was fabricated using isolated top metal electrodes on the upper surface of the BFO membrane during the release of the membrane from an underlying sacrificial, water-soluble SCAO layer. Interestingly, it was found that the isolated electrodes helped immensely in stabilizing the membrane while the SCAO layer was etched away without the formation of cracks or wrinkles in the membrane. Large-size membranes (e.g., membranes with surface areas of greater than 2.0×2.0 mm²) were fabricated in this manner. The strain distribution in the membrane with the isolated platinum (Pt) electrodes was also mapped by finite element analyses using COMSOL. Importantly, as no polymer stamp was used in the membrane transfer and release process, there was no degradation of the thin-film surface quality before or after the membrane fabrication process. Additionally, a similar process was followed using gold (Au) electrodes to stabilize a large-size BFO membrane during release and, once the membrane was released, the Au was removed using a KI solution to obtain an electrode-free, clean, free-standing BFO membrane. As there was no membrane clamping and the strain was released, the BFO membrane performed better than its surface-bound thin-film counterpart, having a lower coercive field and a faster switching response. As such, the free-standing BFO membranes can be used for a variety of device applications, including for low power memory devices.

### Methods

(001) monodomain BFO thin-films were grown on cubic SrTiO₃ (001) substrates with a 4-degree miscut toward [110]. Prior to the deposition of the BFO, a 10 nm-thick Sr₂CaAl₂O₆ (SCAO) layer was grown in a pulsed laser deposition (PLD) chamber at a temperature of 780° C. The SCAO layer was then capped by a 1 nm-thick SrTiO₃ (STO) layer to protect the SCAO layer from moisture when the sample was taken out of the chamber. Then, a bottom electrode layer composed of 25 to 30 nm-thick SrRuO₃ (SRO) was deposited on the STO layer by 90°-off-axis sputtering at 600° C., which was followed by a growth of a 300 nm-thick BFO film by double-gun off-axis sputtering at 750° C. with an Ar:O₂ ratio of 4:1 at a total pressure of 400 mTorr. (Eom, C. B. et al. Applied Physics Letters vol. 55 595-597 (1989); Saenrang, W. et al. Nat. Commun. 8, 1-8 (2017).) The BFO target used contained 5% excess Bi₂O₃ to compensate for bismuth volatility during the thin-film deposition. To enable ferroelectric switching, as well as to support the BFO film during etching of the SCAO layer, a layer of 25-30 nm-thick Pt was deposited and patterned into electrodes via de magnetron sputtering. X-ray diffraction was carried out using a Cu K-a source. Ferroelectric measurements were carried out using a Radiant tester. For coating a polymer support on top of the BFO film, a PMMA layer was spin coated at 5000 rpm for one minute, followed by baking at 180° C. for 5 minutes. Then a PPC layer was coated at 1000 rpm for 1 minute, followed by baking at 45° C. for 60 minutes. COMSOL was used to simulate the strain distribution profile in the BFO membrane during strain release, both without a top polymer support and with isolated Pt top electrodes for a film size of 5×5 mm².

### Results and Discussions

### BiFeO₃ Membrane Fabrication and Characterization

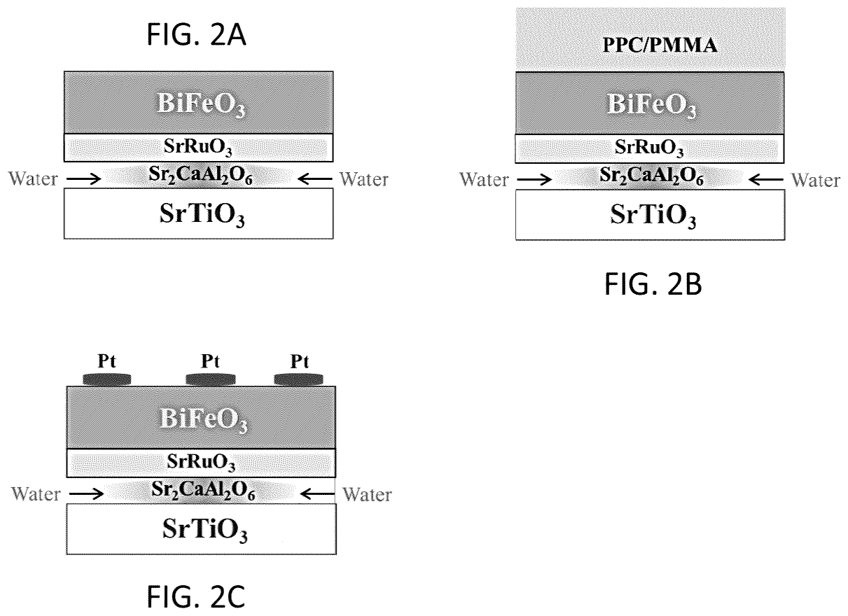

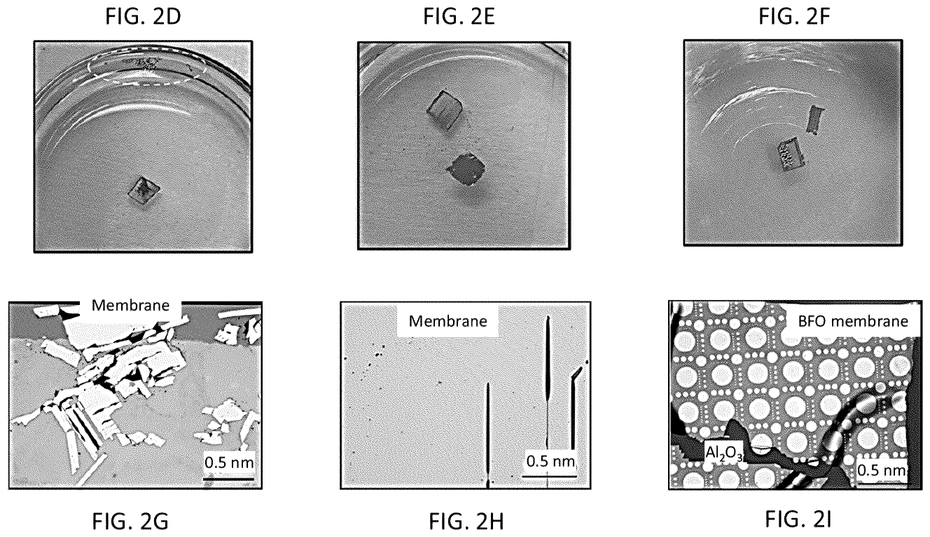

To make BFO membranes, three key methods were tested to etch the sacrificial SCAO layer: (a) membrane release without any top support layer on the BFO; (b) membrane release with a PMMA/PPC top support layer on the BFO; and (c) membrane release with isolated circular Pt electrodes on the BFO, as shown in FIGS. 2A-2I. In the first case, during the etching of the SCAO layer, the BiFeO₃ membrane developed a lot of cracks, leading to small pieces of the membrane floating in water. In the second case, a large 5×5 mm² BFO was released into the water where it floated due to the strong polymer support. Interestingly, for the case of the isolated top Pt metal electrodes, a significantly large 2.5×5 mm² membrane was released and floated in the water, as shown in FIGS. 2D-2F. In all the three cases, the membrane was collected from the water by just scooping the membrane out with an Al₂O₃ supporting substrate. (Chiabrera, F. M. et al. Ann. Phys. 2200084, 1-20 (2022); Zhang, B. et al., Nano-Micro Lett. 13, 1-14 (2021); Ke Gu et al., Adv. Funct. Mater. 30, 2001236 (2020).)

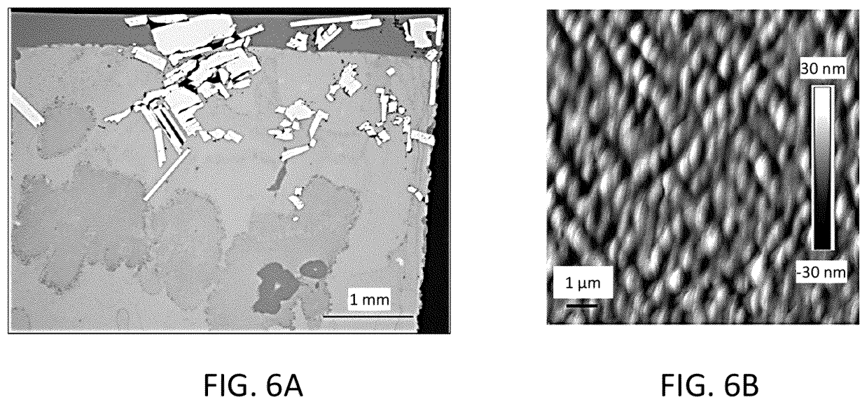

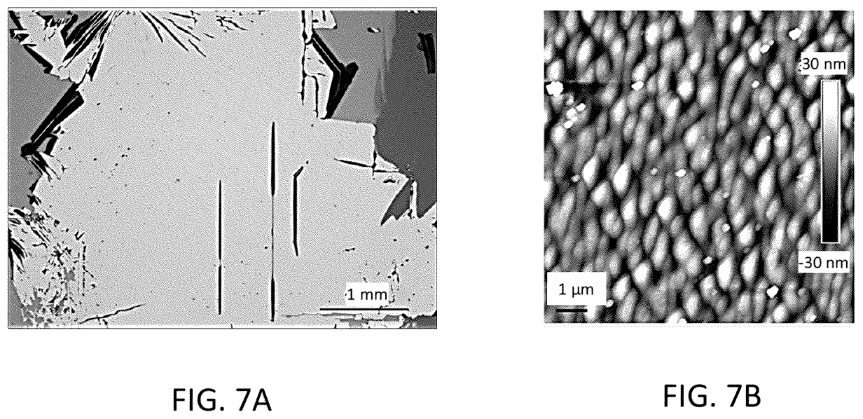

For the first case, the small-size membranes pieces were not suitable for any follow-up device applications, as shown in FIG. 2G and FIGS. 6A-6B. Whereas in the second case, although a large-size membrane was obtained, the membrane surface was never completely free from residual polymer from the support, as shown in FIG. 2H. Clear signatures of polymer residue were seen even after cleaning multiple times with acetone, as shown in FIGS. 7A-7B. Most interestingly, in the third case, as no polymer support was used, a very clean membrane surface that was well-suited for follow-up device fabrication was obtained.

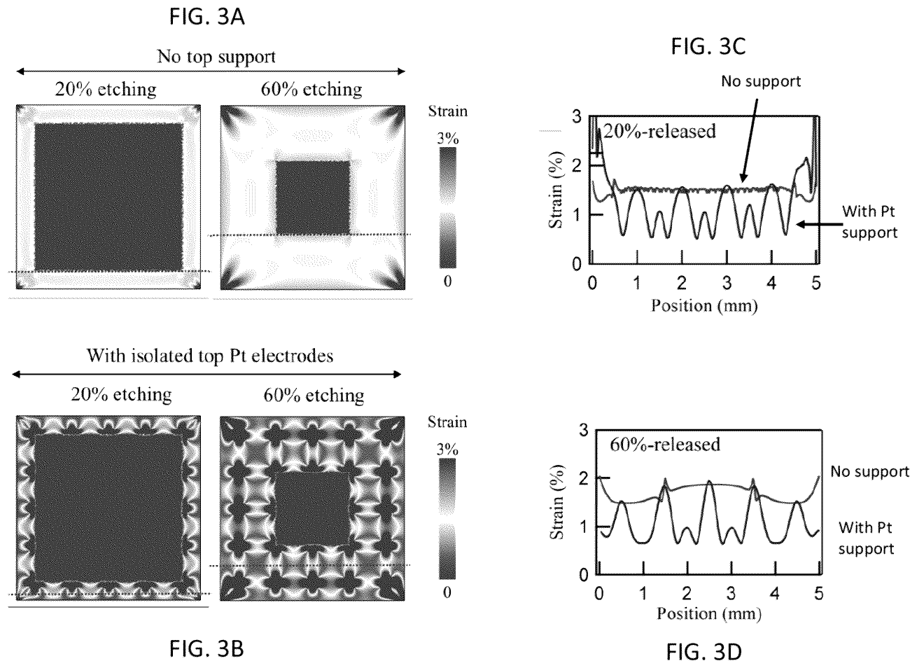

To analyze these results, the role of these Pt electrodes in the stabilization of large complex oxide membranes was studied. To do so, finite element analysis simulations were carried out with a physics-controlled mesh for the case of BFO membrane release without any top electrode(s) and release with, circular top Pt electrodes like those used to form the free-standing BFO membrane. (Marvalova, B. Engineering 4-7 (2016); Ramachandramoorthy, R. et al. Extrem. Mech. Lett. 20, 14-20 (2018).) Ideally, BFP is expected to have ˜1.4% compressive strain on top of SrTiO₃, which is released during etching, so two situations in COMSOL were considered: one for a 20% and one for a 60% etching (i.e., strain release), as shown in FIGS. 3A-3B. When a section profile was taken for both scenarios, it could clearly be seen that the presence of Pt electrodes localized high strain and reduced overall strain, compared to the membrane released without any top electrodes, as shown in FIGS. 3C-3D. Also, Pt is a metal and, therefore, is more ductile than the complex oxide BFO. Thus, during strain release, the isolated Pt electrodes homogenized the strain profile throughout and concentrated higher stain underneath to stabilize large free-standing membranes.

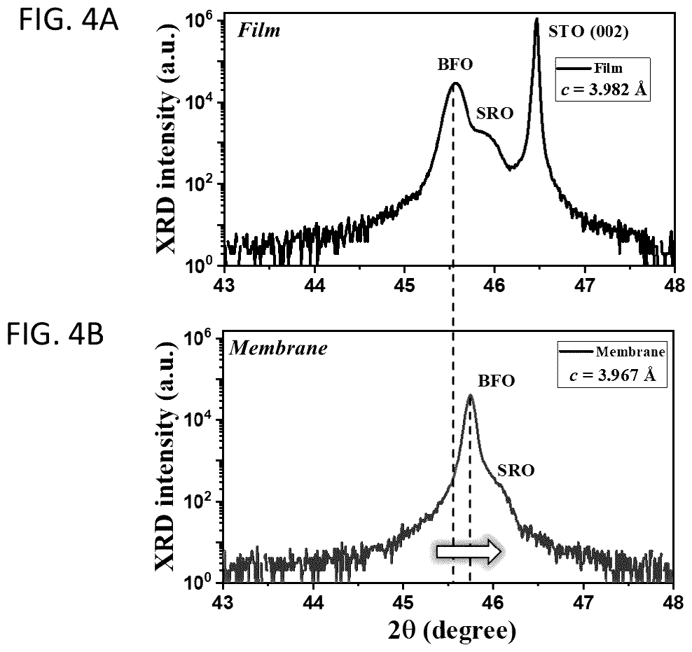

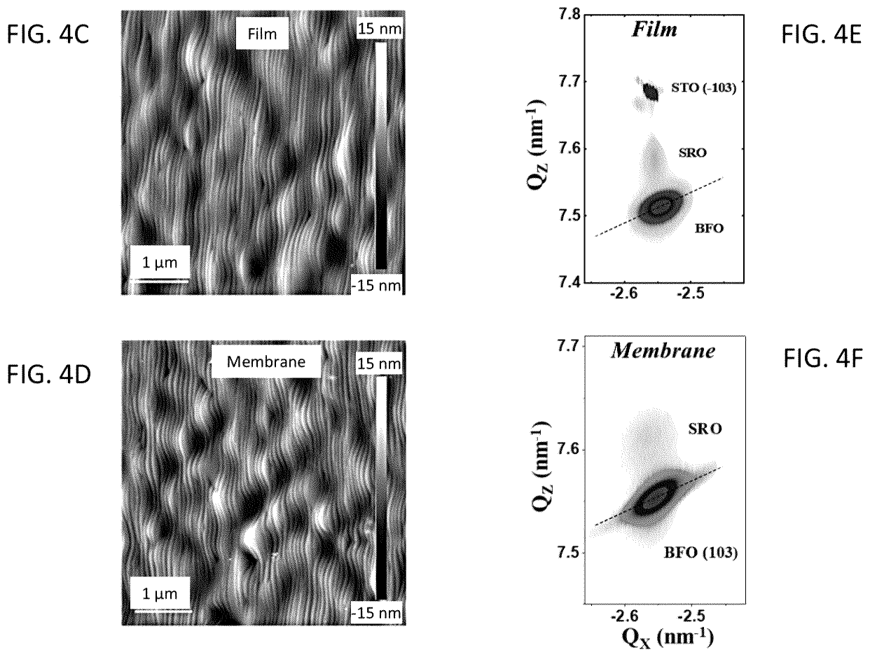

FIGS. 4A-4B show room temperature X-ray diffraction spectra for (FIG. 4A) 300 nm (001) BiFeO₃ thin-film on SrTiO₃ and (FIG. 4B) 300 nm BiFeO₃ membrane collected on Al₂O₃. FIGS. 4C-4D display their corresponding atomic force microscopy (AFM) images exhibiting similar surface quality without any degradation during the etching process. FIGS. 4E-4F show respective reciprocal space mapping images indicating single ferroelastic domain nature for both the film and the membrane.

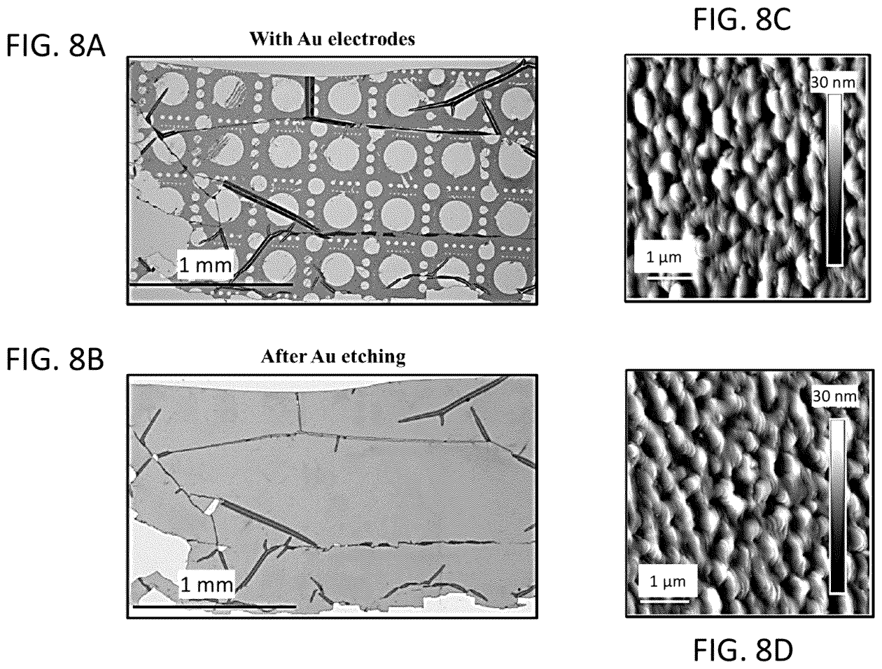

To extend the efficacy of this method to electrode-free, large-area, free-standing membranes, Au electrodes were patterned on top of the BFO thin-films grown on sacrificial SCAO, as described above. Au also helped stabilize the large-size BFO membrane, as shown in FIGS. 8A-8D. The patterned Au electrodes were then completely etched away using KI solution (Green, T. A. Gold Bull. 47, 205-216 (2014)) to produce an electrode-free membrane, as shown in FIG. 8B. Usage of such a solution did not degrade the BFO surface quality, as can be seen from the atomic force microscopy (AFM) images before and after Au removal in FIGS. 8C-8D.

### Structural and Ferroelectric Properties

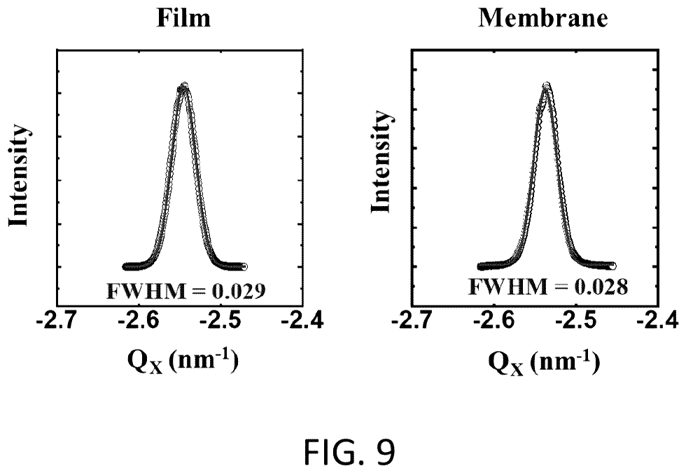

The change in the physical properties of the BFO membranes after releasing the strain induced by the bottom clamped substrate was investigated. X-ray diffraction studies showed that the out-of-plane (002) peak of the BFO was shifted toward a higher angle after release from the substrate, indicating the release of compressive strain in the BFO. This was further confirmed by the out-of-plane lattice parameter of 3.967 Å in the case of the BFO membrane, which was very close to that of the bulk BFO (3.963 Å). (Gustau Catalan, Adv. Mater. 21, 2463 (2009).) AFM images revealed that both the unreleased BFO thin-film and the released BFO membrane were of similar quality, with the clear presence of signature step-bunching features characteristic of a single domain BFO film grown on SrTiO₃ miscut substrates. (Saenrang, W. et al. Nat. Commun. 8, 1-8 (2017); Back, S. H. et al. Nat. Mater. 9, 309-314 (2010); Kim, T. H. et al. Appl. Phys. Lett. 98, 10-13 (2011).) The BiFeO₃ thin-films on the SrTiO₃ substrates with a high-miscut toward the direction grew as single ferroelastic, single ferroelectric, and single antiferromagnetic domain BFO. (Ke, X. et al. Phys. Rev. B—Condens. Matter Mater. Phys. 82, 1-5 (2010); Sichel, R. J. et al. Appl. Phys. Lett. 96, 1-4 (2010); Folkman, C. M. et al., J. Mater. Res. 26, 2844-2853 (2011).) To understand the ferroelastic domain nature, reciprocal space mapping (RSM) around the in-plane (−103) peak was done. The results showed the presence of only one BFO peak both in the thin-film as well as in the membrane, indicating the robust single ferroelastic domain nature. (Back, S. H. et al. Nat. Mater. 9, 309-314 (2010).) Also, cross-sections along the (−103) BiFeO₃ peaks for both the BFO film and the BFO membrane showed no degradation of the crystallinity, as both samples had equal FWHM, as can be seen in FIG. 9.

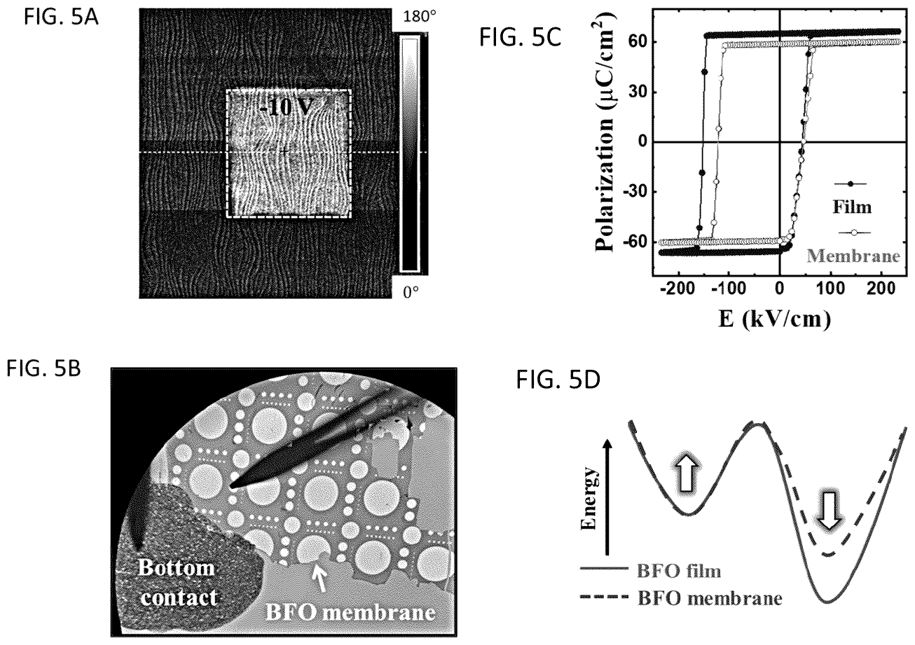

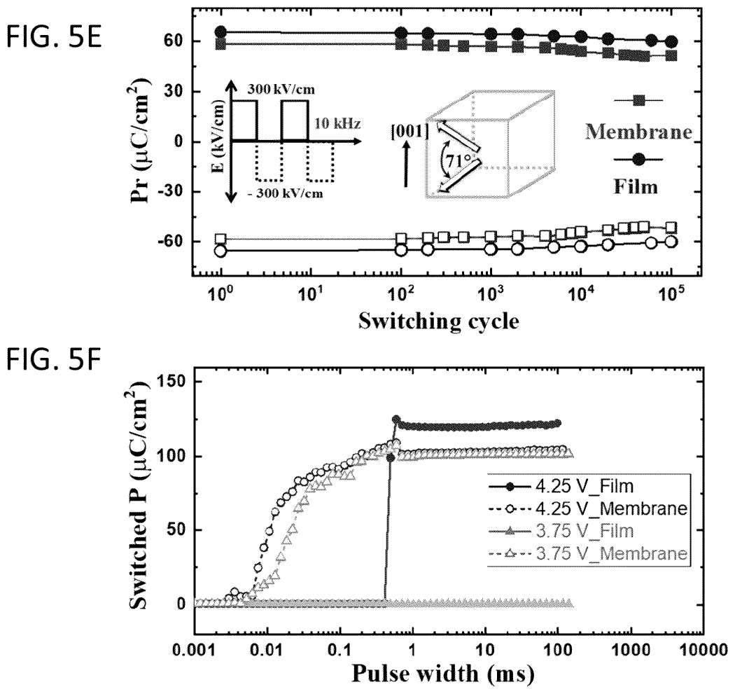

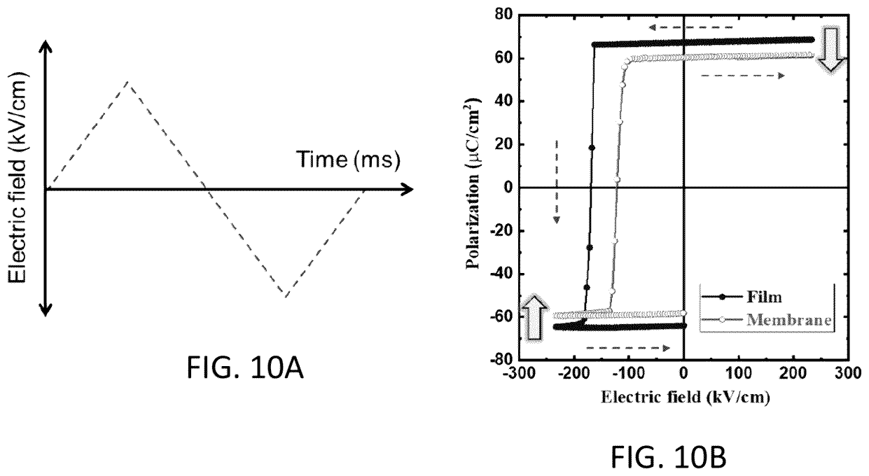

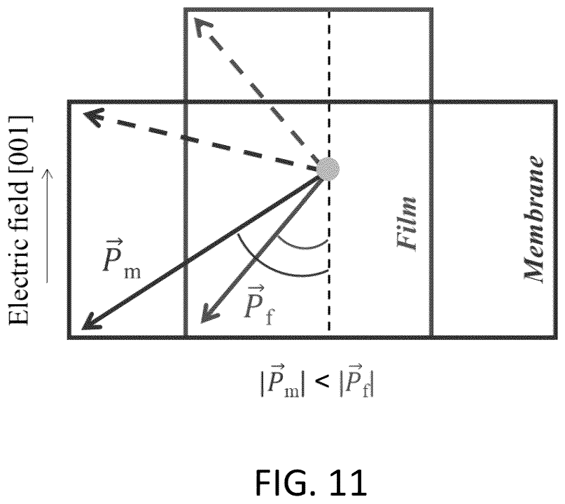

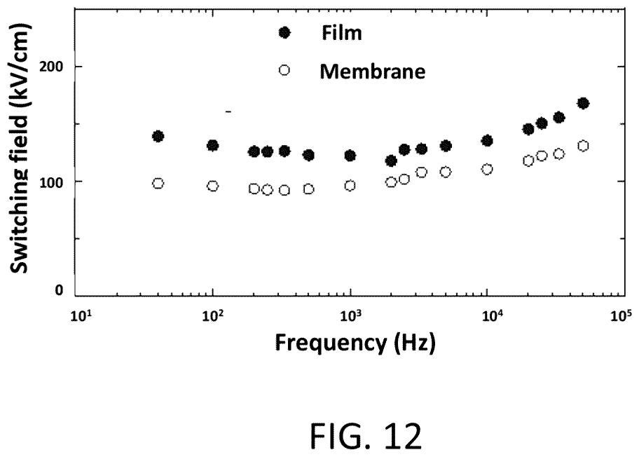

One of the major attractions of the present (001) BFO films grown on SrTiO₃ miscut substrates is that they stabilize in a true monodomain state, i.e., single ferroelastic, ferroelectric, and antiferromagnetic domains, which makes the controllability and understanding of their magnetoelectric multiferroic response much simpler. It has already been shown that the free-standing membrane maintained its single ferroelastic domain nature. To investigate the ferroelectric domain nature, out-of-plane piezo force microscopy was used, as shown in FIG. 5A for the 300 nm-thick BFO membrane. In the as-grown state there was only one contrast indicating the single polarization state, which can be deterministically reversed by the application of a negative electric field. (Back, S. H. et al. 2010.) The single ferroelectric domain state was further verified by electrical measurements, as shown in FIG. 5B, where a bottom contact was made through the electrode. First, polarization versus electric field measurements (P-E loop) without any pre-set electric pulse (which resets the initial polarization state to give rise to a closed P-E loop), were carried out for an applied triangular electric field pulse, as shown in FIGS. 10A-10B, that should show the virgin ferroelectric state of the sample. FIG. 10B, shows that the polarization started with maximum positive value (+Pr) for both the thin-film and the membrane, which strongly indicated the presence of down (↓) polarization (i.e., single ferroelectric domain) in the virgin state of both these samples. Subsequent ferroelectric measurements for the same applied pulse exhibited well-saturated and strong ferroelectric P-E loops for both the film and the membrane, as shown in FIG. 5C. Here, it is interesting to note that the ferroelectric polarization was reduced by ˜10% and coercive field by ˜20%, respectively, in the case of the membrane. Reduction of polarization can be understood from the polarization rotation due to the release of compressive strain, as schematically illustrated in FIG. 11. (Jang, H. W. et al. Phys. Rev. Lett. 101, 3-6 (2008).) The reduction of coercive field, or the ferroelectric imprint (the positive coercive field was smaller than the negative one) in the case of the membrane, can be attributed to the release of the clamping effect of the bottom substrate. (Shi, Q. et al. Nat. Commun. 13, 1-10 (2022); Chen, Z. et al. Sci. Adv. 6, 1-8 (2020).) Also, the presence of asymmetry in the coercive field due to the different types of electrodes (SRO at the bottom and Pt at the top) favored the down ferroelectric polarization state both in the thin-film and the membrane (making it a single ferroelectric domain), as illustrated by the energy diagram in FIG. 5D. The ferroelectric switching field was also found to be less-dispersive and smaller for the membranes for a wide range of frequencies, as shown in FIG. 12, which is also advantageous for the integration of the membranes into electronic devices.

Ferroelectric fatigue measurements were done to test the robustness of electric field switching on both the film and the membrane, as shown in FIG. 5E. Interestingly, both the film and the membrane exhibited deterministic 71°-type switching over 100,000 cycles without any degradation, which makes the membrane very useful for its integration into magnetoelectric memory devices for further testing. FIG. 5D shows that the effective energy barrier in the case of the membrane was reduced. Thus, to test the switching response with time, the FE polarization was measured with applied pulse width for different voltages, as shown in FIG. 5F. The membrane outperformed its thin-film counterpart. Switching time in the membrane was reduced by ˜60% as compared to its corresponding thin-film, even at lower voltage, which is very useful for low power magnetoelectric memory applications.

This Example successfully demonstrates an alternative method for fabrication of large-area, high-quality, polymer-free BFO free-standing membranes by using isolated top metallic electrodes during membrane release from an underlying substrate. Using finite element analysis by COMSOL, the critical role of the isolated electrodes in the homogeneous distribution of mechanical strain during release from the substrate and the stabilization of large-size membranes (>2×2 mm²) was demonstrated and the structural and electrical properties of the membranes were characterized. The free-standing membranes were found to be of single ferroelastic and single ferroelectric domain state, like the corresponding thin-film, without any degradation of the quality. The membranes exhibited deterministic switching over a hundred thousand electric field cycles at lower voltage and with faster switching dynamics than their thin-film counterparts.

### Metal Island Shape, Dimensions, and Density

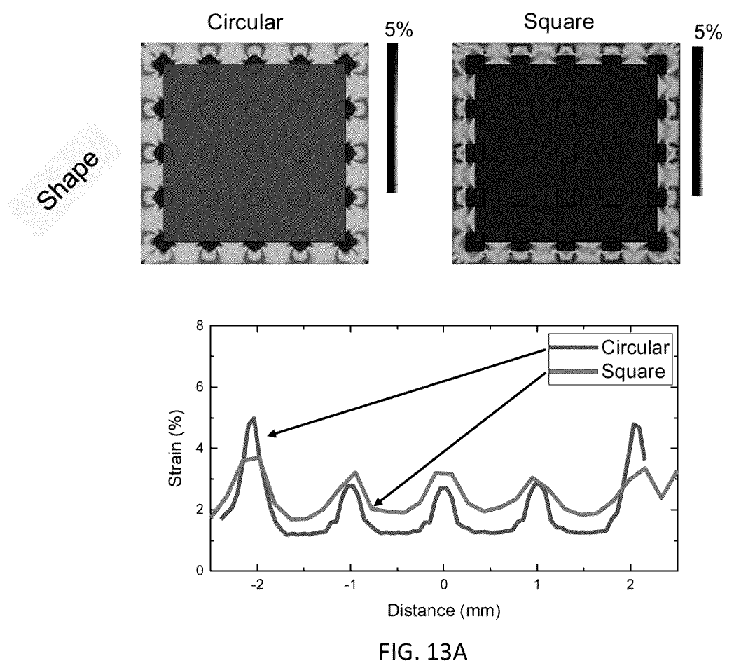

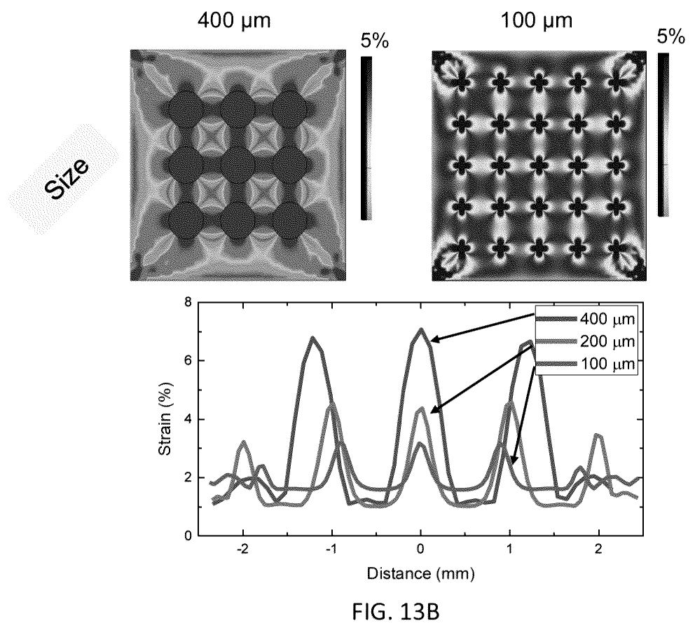

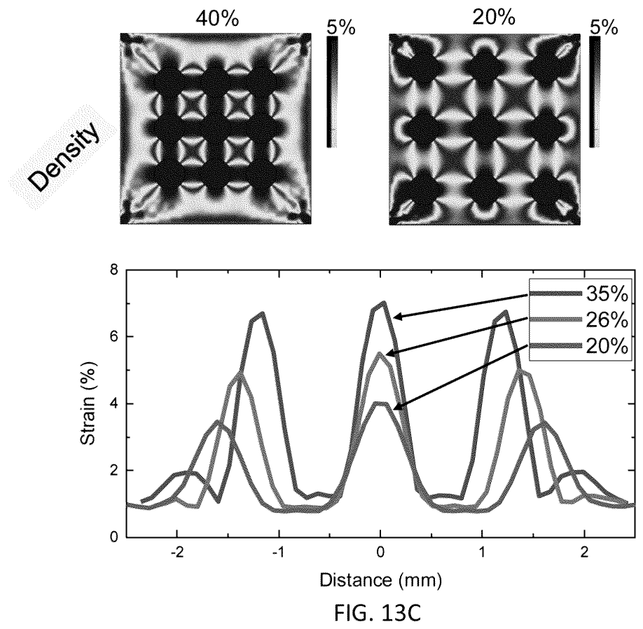

The effect of metal island shape, size, and density on the strain distribution in the BFO membranes was also studied using 2D Comsol simulations. The results are shown in FIGS. 13A, 13B, and 13C. FIG. 13A shows strain distribution images for a circular (FIG. 13A, top left panel) and square (FIG. 13A, top right panel) Pt islands on a BFO membrane. The corresponding line-cuts are shown in FIG. 13A, bottom panel. As shown in these figures, the circular island was better at minimizing and distributing strain than a similarly dimensioned square island.

FIG. 13B shows strain distribution images for differently sized circular islands. Strain distribution images for circular Pt islands having a radius of 400 μm (FIG. 13B, top left panel) and 100 μm (FIG. 13B, top right panel) on a BFO membrane were obtained. The corresponding line-cuts are shown in FIG. 13B, bottom panel. As shown in these figures, circular islands of radius 100 to 200 μm provided better strain stabilization in the membrane than did a circular island having a radius of 400 μm.

FIG. 13C shows strain distribution images for BFO membranes with different circular Pt island densities. Strain distribution images for BFO membranes having a 40% surface area coverage (FIG. 13C, top left panel) and 20% surface area coverage (FIG. 13C, top right panel) were obtained. The corresponding line-cuts are shown in FIG. 13C, bottom panel. As shown in these figures, island densities corresponding to 20% to 30% membrane surface area coverage provided better strain release and stabilization of the membrane than did an island density corresponding to a surface area coverage of 35% or higher.

While BFO was used as an illustrative complex oxide in the Example, the procedures described herein can also be used to form free-standing membranes of other complex oxide materials using sacrificial layers that can be selectively etched for membrane release.

### Example 2: Fabrication of Free-Standing Complex Nitride Membranes

This Example illustrates the fabrication of a free-standing antiperovskite manganese gallium nitride (Mn₃GaN) membrane. The inventors believe this is the first report of the fabrication of a free-standing Mn₃GaN membrane. Thus, although the membrane in this example was released using metal islands to achieve a large-size, high-quality, organic residue free membrane, the present disclosure also covers methods of fabricating free-standing Mn₃GaN membranes that do not include the use of the metal islands during the release of the Mn₃GaN film from an underlying substrate.

### Methods

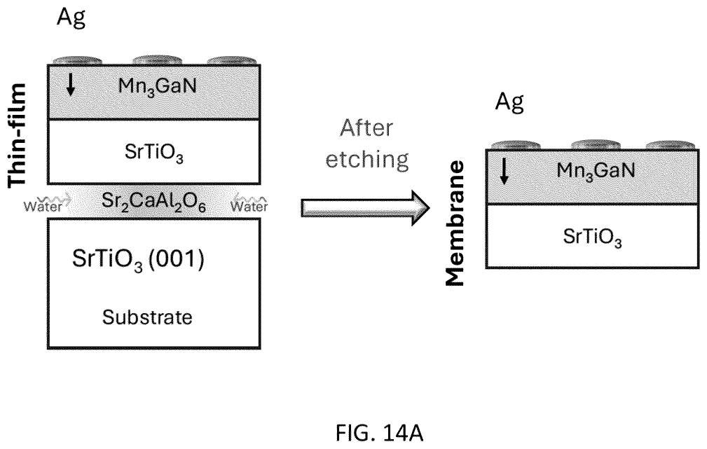

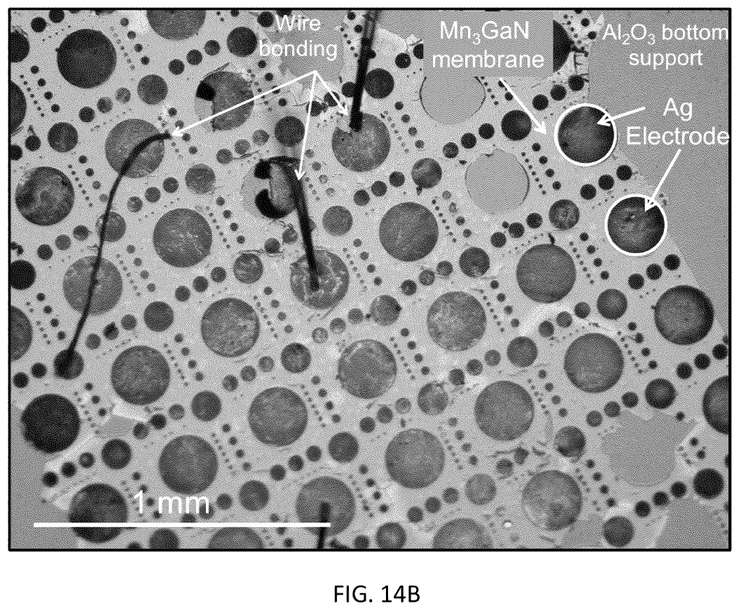

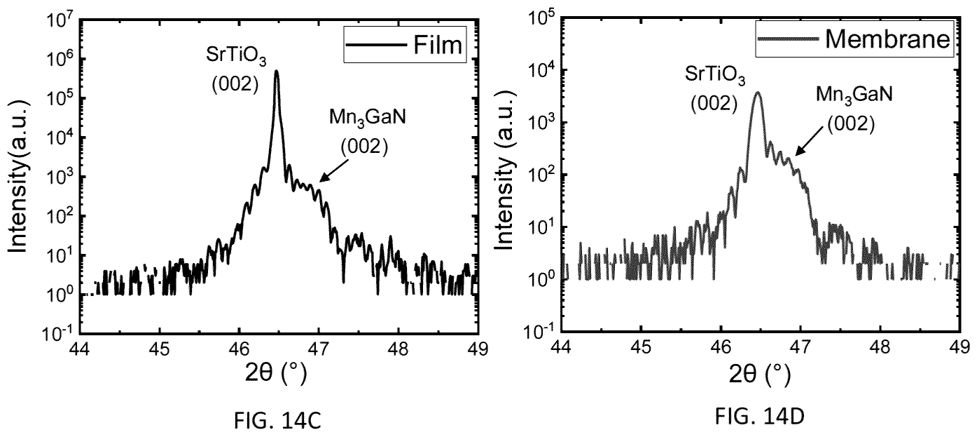

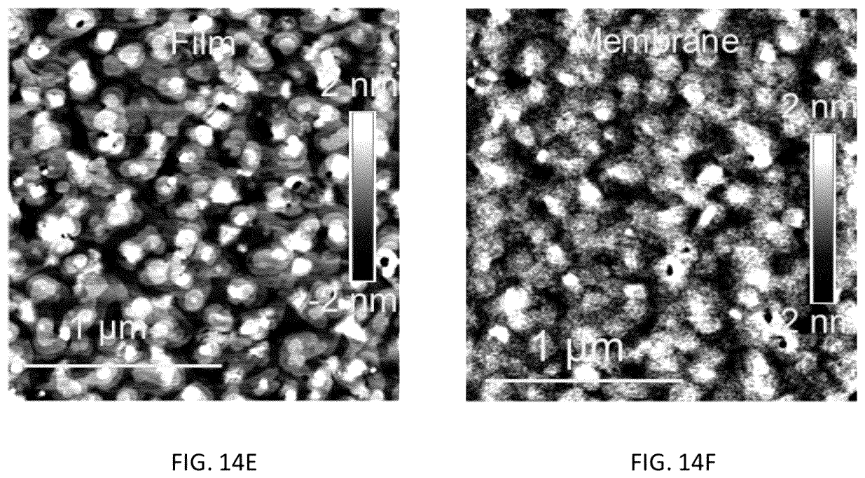

Mn₃GaN epitaxial thin films were grown on (001) SrTiO₃ substrates with a miscut of less than 0.1 degree. Prior to depositing the Mn₃GaN, a 10 nm-thick SCAO sacrificial layer and an 80 nm-thick STO layer were grown by pulsed laser deposition (PLD) at temperatures of 780° C. and 770° C., respectively. After cooling to room temperature in an O₂ gas environment, the sample was removed from the chamber and dipped into buffered hydrofluoric acid (BHF) for 2 seconds to produce TiO₂ single surface termination on the SrTiO₃ layer. Next, 25 nm-thick Mn₃GaN films were grown by DC reactive sputtering using a Mn₃Ga alloy target at 550° C. with an Ar:N₂ ratio of 4:1 and a total pressure of 10 mTorr. (Nan, Tianxiang, et al. “Controlling spin current polarization through non-collinear antiferromagnetism.” Nature communications 11.1 (2020): 4671) 200 nm-thick patterned Ag electrodes (metal islands) were fabricated using the lift-off technique (although a thinner Ag layer would suffice to stabilize the membrane, this thickness was chosen to ensure robust wire bonding for electrical measurements). The sample was then floated on water after dissolving the SCAO sacrificial layer to obtain the Mn₃GaN free-standing membrane. Once the membrane was etched and floated on water, it was collected by directly scooping it onto a desired substrate. The fabrication process is shown schematically in FIG. 14A.

### Characterization

X-ray diffraction was performed using a Cu K_{α} source to determine the crystalline quality before and after membrane fabrication. Magnetic and transport properties were measured using the Quantum Design Magnetic Properties Measurement System and the Physics Properties Measurement System, respectively. Upon complete etching of the SCAO, a reasonably large Mn₃GaN membrane was achieved.

FIG. 14B shows optical microscopy images of the large Mn₃GaN membrane supported by isolated top metal electrodes. To determine whether the membrane fabrication process has degraded the structural and physical properties, both the thin film and the membrane of Mn₃GaN antiperovskite were characterized. The out-of-plane X-ray diffraction data around the SrTiO₃ (002) peak, as shown in FIGS. 14C and 14D, reveal a strong Mn₃GaN peak along with distinct Kiessig fringes, indicating high crystalline quality and a pristine interface for both the Mn₃GaN thin film and membrane. (Quintela, Camilo X., et al. “Epitaxial antiperovskite/perovskite heterostructures for materials design.” Science Advances 6.30 (2020): eaba4017) There was no degradation in surface morphology, as the atomic force microscopy images show an atomically smooth surface with a roughness of ˜0.3 nm, as depicted in FIGS. 14E and 14F for both the thin film and membrane. This is desirable for follow-up device fabrication.

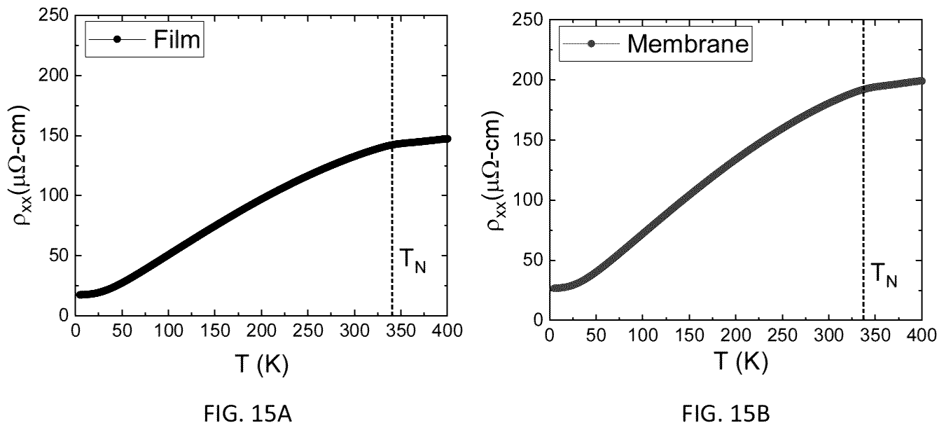

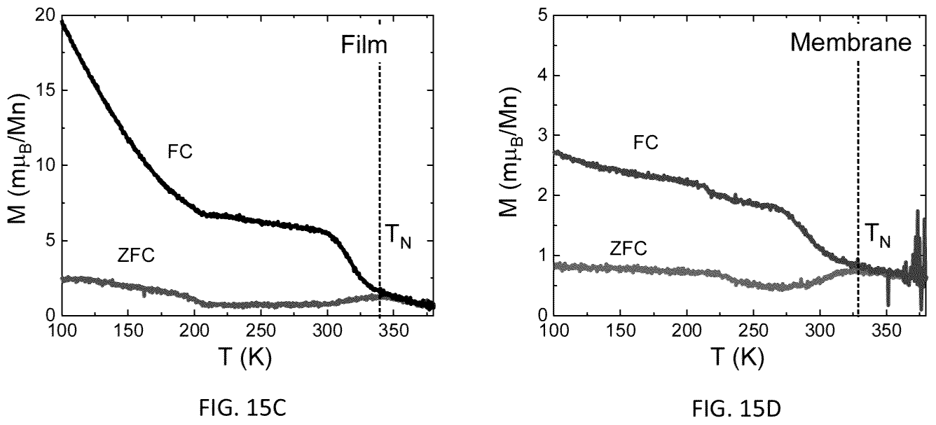

Electronic transport measurements were performed in a van der Pauw geometry, and longitudinal and transverse resistivities were measured over a temperature range of 2 K to 400 K. The sheet resistance versus temperature plots in FIGS. 15A and 15B show good metallic behavior with a clear paramagnetic to antiferromagnetic transition around ˜340 K (Nan et al., 2020) for both the thin film and membrane of Mn₃GaN. Temperature-dependent magnetization data also clearly show a similar magnetic transition for both the thin film and membrane, as shown in FIGS. 15C and 15D. These data indicate that both the Mn₃GaN film and the membrane maintain high sample quality during the membrane fabrication process. The slight shift in the Neel transition temperature and the reduced magnetic moment in the membrane are due to strain release from the thin film, resulting in physical properties close to the bulk values.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” can mean “one or more” or only one. Embodiments of the invention consistent with either meaning are covered.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. A method of forming a membrane, the method comprising:
providing an epitaxial heterostructure comprising: a substrate; a strained film comprising a single-crystal complex oxide or a single-crystal complex nitride in a strained state; and a sacrificial layer between the substrate and the strained film;
forming metal islands on the top surface of the strained film; and
immersing the epitaxial heterostructure in a liquid comprising an etchant to selectively etch away the sacrificial layer and release the strained film from the epitaxial heterostructure as a membrane of the single-crystal complex oxide or the single-crystal complex nitride, wherein the membrane is released without a top support, other than the metal islands, on its top surface.

2. The method of claim 1, further comprising removing the metal islands from the membrane.

3. The method of claim 1, wherein the strained film comprises the single-crystal complex oxide and the single-crystal complex oxide is a single-crystal complex perovskite oxide.

4. The method of claim 1, wherein the substrate comprises SrTiO₃ or GdScO₃.

5. The method of claim 4, wherein the sacrificial layer comprises a (Ca,Sr,Ba)₃Al₂O₆ oxide, LaₓSr₁₋ₓMnO₃, where 0<x<1, SrRuO₃, or SrVO₃.

6. The method of claim 5, wherein the strained film comprising the single-crystal complex oxide, and the single-crystal complex oxide is selected from: SrTiO₃, LaₓSr₁₋ₓMnO₃, BaTiO₃, BiFeO₃, SrRuO₃, LaNiO₃, BiMnO₃, Sr₂IrO₄, La_{0.7}Ca_{0.3}MnO₃. [(La_{0.7}Ca_{0.3}MnO₃)₅/(SrTiO₃)₅]ₙ, BaTiO₃/La_{0.7}Sr_{0.3}MnO₃, BaTiO₃/La_{0.7}Sr_{0.3}MnO₃/BaTiO₃, LaAlO₃/YBa₂Cu₃O₇₋ₓ/LaAlO₃, La_{0.7}Sr₃MnO₃/BiFeO₃, BaTiO₃—CoFe₂O₄, PbTiO₃, n-SrTiO₃/n-PbTiO₃/n-SrTiO₃, [(PbTiO₃)₁₆/(SrTiO₃)₁₆]₈, Ba₃Al₂O₆, PbZr_{0.2}Ti_{0.8}O₃, [(CaTiO₃)ₙ/(SrTiO₃)ₙ]₆, BiFeO₃/SrRuO₃, LiFe₅O₈, SrRuO₃/BaTiO₃/SrRuO₃, Ba₁₋ₓSrₓRuO₃/Ba₁₋ₓSrₓTiO₃/Ba₁₋ₓSrₓRuO₃, La_{0.7}Sr_{0.3}MnO₃, La_{0.7}Sr_{0.3}MnO₃, BaTiO₃/SrTiO₃, and CaFe₂O₄.

7. The method of claim 1, further comprising removing the released membrane from the liquid on the surface of a support platform.

8. The method of claim 7, wherein the released membrane on the surface of the support platform is free of cracks and wrinkles over an area of at least 4 mm².

9. The method of claim 8, wherein the strained film comprises the single-crystal complex oxide and the single-crystal complex oxide is a single-crystal complex perovskite oxide.

10. The method of claim 9, wherein the single-crystal complex perovskite oxide is single-crystal BiFeO₃.

11. The method of claim 10, wherein the strained film is a bilayer comprising a sublayer of the single-crystal BiFeO₃ and a sublayer of SrRuO₃.

12. The method of claim 11, wherein the single-crystal BiFeO₃ has a single ferroelastic, a single ferroelectric, and a single antiferromagnetic domain.

13. The method of claim 1, wherein the strained film is a bilayer comprising a sublayer of an antiperovskite manganese nitride on a sublayer of SrTiO₃.

14. A supported complex nitride membrane comprising a membrane bilayer consisting of a sublayer of an antiperovskite manganese nitride and an adjacent sublayer of SrTiO₃ on a surface of a support platform, wherein the SrTiO₃ sublayer is in contact with, but does not form an epitaxial interface with, the surface of the support platform.

15. The supported complex nitride membrane of claim 14, wherein the antiperovskite manganese nitride is Mn₃GaN, Mn₃SnN, Mn₃NiN, or Mn₃PtN and the membrane bilayer has a thickness of no greater than 500 nm.

16. A supported complex oxide membrane consisting of one or more layers of single-crystal perovskite oxide on a surface of a support platform, wherein one of the layers of single-crystal perovskite oxide is in contact with, but does not form an epitaxial interface with, the surface of the support platform, and further wherein the one or more layers of single-crystal perovskite oxide are free polymer residues and free of cracks and wrinkles over an area of at least 10 mm².

17. The complex oxide of claim 16, wherein at least one of the one or more layers of single-crystal perovskite oxide is a layer of single-crystal BiFeO₃.

18. The complex oxide of claim 17, wherein the complex oxide membrane comprises the layer of single-crystal BiFeO₃ and a layer of single-crystal SrRuO₃.

19. The complex oxide of claim 18, wherein the single-crystal BiFeO₃ has a single ferroelastic, a single ferroelectric, and a single antiferromagnetic domain.

20. The complex oxide of claim 16, wherein the complex oxide membrane is a bilayer membrane consisting of only the layer of single-crystal BiFeO₃ and the layer of single-crystal SrRuO₃.
